(19) United States
(12) Patent Application Publication
(10) Pub. No.: US 2026/0343831 A1
(43) Pub. Date: Oct. 29, 2026

(54) POWER MODULE WITH THERMALLY CONDUCTIVE SHEET

(71) Applicant: TDK-Lambda Americas, Inc., Richardson, TX (US)

(72) Inventor: Gordon K. Y. Lee, Allen, TX (US)

(21) Appl. No.: 19/188,606

(22) Filed: Apr. 24, 2025

(51) Int. Cl. H05K 7/20

(52) U.S. Cl. CPC H05K 7/209; H05K 7/20463; H05K 7/20481

(57) ABSTRACT

An apparatus, system, and method for thermal management. The apparatus includes a power supply that is at least partially enclosed by a heat sink. The power supply comprises heat-generating electrical components disposed on one side of a planar substrate. The heat-generating electrical components include a set of thermal limiting components and a set of non-thermal limiting components. The power supply also includes a flexible, thermally conductive sheet, wherein one side of the thermally conductive sheet is coupled to the surface of at least one thermal limiting component and the other side is coupled to the heat sink. The flexible, thermally conductive sheet transfers heat generated by the thermal limiting component to the heat sink.

### TECHNICAL FIELD

The present disclosure relates in general to the field of heat management in electronic devices, and more particularly to a novel apparatus for achieving a more uniform distribution of heat across the various components within an electronic device, as well as a system and methods of use.

### BACKGROUND

Components of electronic devices operate most efficiently only within a defined temperature range, which varies among the various components of an electronic device. Excessive heat-generation during operation of an electronic device can adversely affect the performance of these components, as well as the overall performance and stability of the system. For example, elevated temperatures can lead to a reduction in processing speed, compromised reliability, and accelerated degradation of both individual components and the system as a whole. Consequently, effective heat management is a fundamental consideration in the design and operation of electronic devices.

In recent years, power supplies have steadily increased in power level while overall size is maintained or reduced. Conventional heat management systems are often insufficient to dissipate heat in modern power supplies with increased power density. As power density continues to increase, improved thermal management is necessary to prevent overheating and maintain optimal performance.

### SUMMARY

Novel aspects of the present invention are directed to an apparatus comprising a power supply that is at least partially enclosed by a heat sink. The power supply comprises a plurality of heat-generating electrical components disposed on one side of a planar substrate. The heat-generating electrical components include a set of thermal limiting components and a set of non-thermal limiting components. The power supply also includes a flexible, thermally conductive sheet, wherein one side of the thermally conductive sheet is coupled to the surface of at least one thermal limiting component and the other side is coupled to the heat sink. The flexible, thermally conductive sheet transfers heat generated by the thermal limiting component to the heat sink.

In another embodiment, novel aspects of the present invention are directed to a system comprising a power module that includes a power supply at least partially enclosed by a heat sink and a set of subsystems electrically coupled to the power module. The power supply comprises a set of thermal limiting components disposed on one side of a planar substrate, wherein the thermal limiting components are electrical components that tend to exceed their maximum operating temperature during operation of the power supply. The power supply also includes a set of non-thermal limiting components disposed on one side of a planar substrate, wherein the non-thermal limiting components are electrical components that tend to operate below their maximum operating temperatures. The power supply also comprises a flexible, thermally conductive sheet coupled to a surface of at least one component from the set of thermal limiting components and the heat sink. The thermal limiting components and the non-thermal limiting components generate heat during operation of the power supply. The flexible, thermally conductive sheet distributes the heat from the thermal limiting components to the heat sink, and the heat sink distributes heat to the surrounding environment.

In yet another embodiment, novel aspects of the present invention are directed to a method for manufacturing an apparatus that can achieve a more uniform distribution of heat across the various components within an electronic device. The method includes the steps of identifying a set of thermal limiting components and a set of non-thermal limiting components from a plurality of electrical components of the power supply; disposing a thermal interface material in thermal contact with at least one component of the set of non-thermal limiting components; disposing a gap filler in thermal contact with a flexible, thermally conductive sheet and at least one component from the set of non-thermally limiting components; and coupling the flexible, thermally conductive sheet to a surface of at least one component from the set of thermal limiting components on a first side of the flexible, thermally conductive sheet and the heat sink on an opposite side of the flexible, thermally conductive sheet.

Other aspects, embodiments, and features of the invention will become apparent from the following detailed description of the invention when considered together with the accompanying figures. In the figures, each identical or substantially similar component that is illustrated in various figures is represented by a single numeral or notation. For the purposes of clarity, not every component is labeled in every figure. Nor is every component of each embodiment of the invention shown where illustration is not necessary to allow those of ordinary skill in the art to understand the invention.

### BRIEF DESCRIPTION OF THE DRAWINGS

The novel features believed characteristic of the disclosure are set forth in the appended claims. The disclosure itself, however, as well as a preferred mode of use, further objectives, and advantages thereof, will be best understood by reference to the following detailed description of illustrative embodiments when read in conjunction with the accompanying drawings, in which:

FIG. 1 illustrates a partially exploded view of one embodiment of an apparatus with a flexible, thermally conductive sheet providing improved heat distribution in accordance with the disclosed principles;

FIG. 2A illustrates a cross-sectional side view of an exemplary embodiment of the apparatus with improved heat distribution from line A-A′ shown in FIG. 3;

FIG. 2B illustrates a cross-sectional side view of an exemplary embodiment of the apparatus with improved heat distribution from line A-A′ shown in FIG. 3;

FIG. 3 illustrates a top view of an exemplary embodiment of the apparatus with improved heat distribution;

FIG. 4 illustrates an exploded view of an exemplary embodiment of a flexible thermally conductive sheet for use in accordance with the disclosed principles;

FIG. 5 illustrates top view of an exemplary embodiment of the apparatus with improved heat distribution implementing two thermally conductive sheets; and

FIG. 6 is a flowchart illustrating a method of heat management in an electronic device in accordance with the disclosed principles.

INDEX OF REFERENCE NUMERALS AND DEFINITIONS

| Reference | Element |
|---|---|
| 100 | apparatus |
| 102 | heat sink |
| 104 | power supply |
| 106 | base |
| 108 | lid |
| 110 | substrate |
| 112 | heat-generating components |
| 112a | thermal limiting components |
| 112b | non-thermal limiting components |
| 112c | low thermal tolerance thermal limiting components |
| 118 | thermally conductive sheet |
| 120 | gap filler |
| 122 | thermal interface material |
| 400 | thermally conductive sheet |
| 402 | graphite sheet |
| 404a | electrically insulative sheet |
| 404b | electrically insulative sheet |
| 500 | apparatus |
| 502 | thermally conductive sheet |
| 504 | thermally conductive sheet |
| 600 | flowchart |
| 602 | step 1 |
| 604 | step 2 |
| 606 | step 3 |
| 608 | step 4 |
| 610 | step 5 |
| 612 | step 6 |
| 700 | graph |

### DETAILED DESCRIPTION

Power supply systems are a major source of heat in electronic devices. Heat-generating components within a power supply system are typically characterized by varying constructions, temperature ratings, and power ratings, which results in a non-uniform thermal distribution across the system. As a consequence, the thermal profile of a power supply often exhibits distinct clusters of hot spots and cooler regions. This uneven heat distribution can lead to inefficiencies, as certain components operate near their thermal limits while others remain underutilized in terms of their thermal capacity.

Novel aspects of this disclosure recognize the need for an apparatus that can achieve a more uniform distribution of heat across the various components within an electronic device. To this end, an improved heat distributed device is provided that can spread heat along a conductive pathway to cool components that tend to limit the performance of an electronic device due to elevated temperatures.

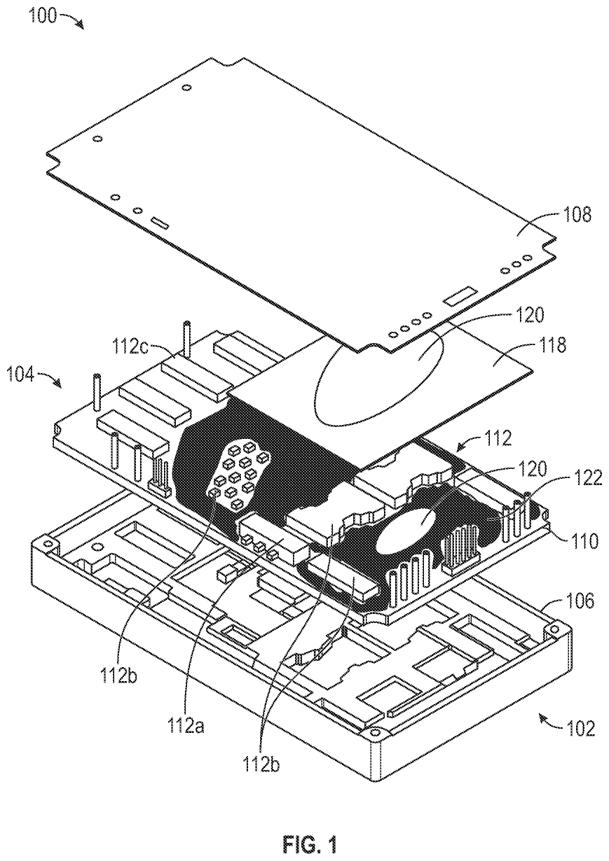

Referring to FIG. 1, illustrated is a partially exploded perspective view of one embodiment of an apparatus 100 designed and constructed in accordance with the disclosed principles. The apparatus 100 includes a heat sink 102 at least partially enclosing a power supply 104.

In the non-limiting embodiment depicted in FIG. 1, the heat sink 102 is a rigid body composed of a thermally conductive material. Examples of thermally conductive materials that can be used to form the heat sink 102 include a metal or alloy, including but not limited to aluminum and copper. The heat sink 102 is positioned in thermal contact with a power supply 104 (described below), such that the heat sink 102 can absorb heat generated by a power supply 104 and dissipate the heat into the surrounding environment, thereby cooling the power supply 104. The heat sink 102 is also configured to at least partially enclose the power supply 104. In the non-limiting exemplary embodiment depicted in FIG. 1, the heat sink 102 may be a case comprising a base 106 and a lid 108. The base 106 and lid 108 may be removably attached to enclose the power supply 104 and create thermal contact between the heat sink 102 and the power supply 104.

The apparatus 100 also includes a power supply 104 comprising various heat-generating components 112 mounted on a substrate 110. The substrate 110 may be a planar, rigid body, such as a printed circuit board (PCB), which can be positioned substantially parallel to the heat sink 102. In the non-limiting exemplary embodiment depicted in FIG. 1, the heat-generating components are disposed on one side of the substrate 110. The functionality of the heat-generating components is at least partially dependent on their temperature. That is, the performance of the heat-generating components can deteriorate as temperature increases. More specifically, the heat-generating components are designed to reduce performance when approaching critical temperatures to avoid damage from overheating. The heat-generating components include a set of thermal limiting components 112a and a set of non-thermal limiting components 112b (collectively referred to as heat-generating components 112). The functionality of heat generating components 112 is temperature dependent. Thermal limiting components 112a are heat-generating components 112 that are characterized by a tendency to limit the performance of the power supply 104 during operation due to elevated temperatures. That is, the thermal limiting components 112a tend to exceed their maximum temperature rating and cause reduced performance to avoid damage from overheating. Non-thermal limiting components 112b, on the other hand, are characterized by a tendency to operate below their maximum temperature rating. At least some of the novel aspects of the present disclosure provide for a thermally conductive, electrically insulated pathway which prevents the thermal limiting components 112a from exceeding their maximum temperature rating, but which also provides a more uniform distribution of heat.

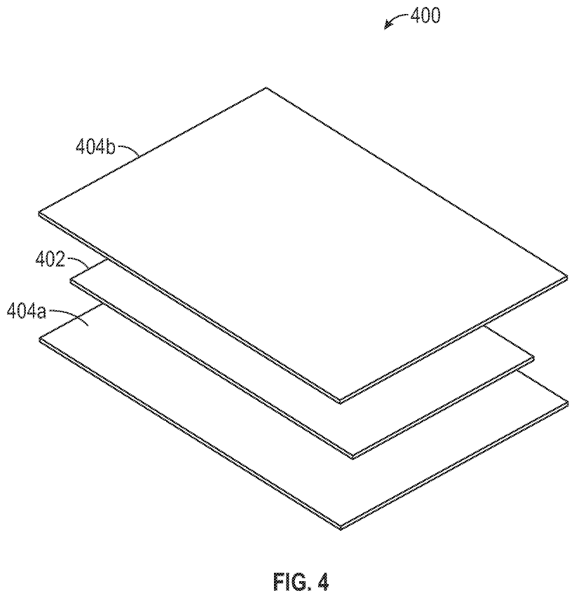

The thermally conductive, electrically insulated pathway is provided by a thermally conductive sheet 118. The thermally conductive sheet 118 is a pliable, heat-conductive sheet. The thermally conductive sheet 118 may be formed from any appropriate material for distributing heat within the power supply 104. For example, the thermally conductive sheet 118 may be composed of natural or synthetic graphite. Graphite has a relatively high heat conductivity in the x-y plane, with an x-y thermal conductivity as high as 1900 W/mK. Additionally, graphite can be formed into a thin and flexible sheet such that it can be conformed to geometry of the differently sized components of the power supply 104, which facilitates the cooling of multiple components at a given time. An embodiment of a thermally conductive sheet 118 is illustrated in FIG. 4.

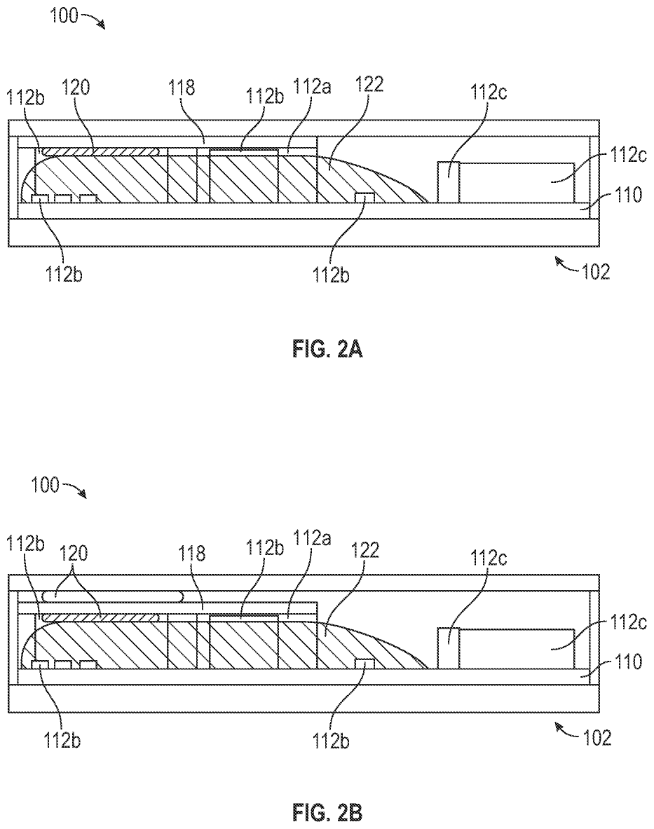

Referring to FIG. 2A, illustrated is a cross-sectional side view of an exemplary apparatus 100. In this non-limiting exemplary embodiment, the thermally conductive sheet 118 is sized and positioned to be in thermal contact with the surface of at least one thermal limiting component 112a. Heat generated by the thermal limiting component 112a is thereby spread into the thermally conductive sheet 118 and the temperature of the thermal limiting components 112a is decreased. As illustrated in FIG. 1, the surface area of the thermally conductive sheet 118 may be larger than the area of contact with the thermally limiting component 112a such that the thermally conductive sheet 118 spreads heat from the thermal limiting component 112a in the x-y direction, i.e., along its x-y plane, thereby further reducing the temperature of the thermal limiting components 112a. Referring again to FIG. 2A, the thermally conductive sheet 118 may also sized and positioned to be in thermal contact with the heat sink 102. Accordingly, the thermal limiting components 112a are thermally joined to the heat sink 102 by the thermally conductive sheet 118. Heat generated by the thermal limiting components 112a is thereby spread in the positive z-direction to the heat sink 102. In this way, the thermally conductive sheet 118 acts as a heat spreader to dissipate the heat generated by the thermal limiting components 112a into the surrounding environment. While FIG. 2A illustrates coupling the thermally conductive sheet 118 to the heat sink 102, in another embodiment the thermally conductive sheet 118 is not coupled to the heat sink 102. That is, the thermally conductive sheet 118 may spread heat away from the thermal limiting components 112a in the x-y direction, i.e., along its x-y plane, thereby further reducing the temperature of the thermal limiting components 112a, without transferring heat to the heat sink 102 via conduction.

The thermally conductive sheet 118 may also be sized and positioned to be in thermal contact with the surface of at least one non-thermal limiting component 112b. Accordingly, the thermal limiting components 112a may be thermally joined to the non-thermal limiting components 112b by the thermally conductive sheet 118. Heat may thereby be spread from the thermal limiting components 112a to the non-thermal limiting components 112b, which further reduces the temperature of the thermal limiting components 112a. As previously mentioned, non-thermal limiting components 112a tend to operate below their maximum temperature rating. Accordingly, spreading heat from the thermal limiting components 112a to the non-thermal limiting components 112b improves the performance of the thermal limiting components 112a without compromising the performance of the non-thermal limiting components 112b.

In the non-limiting embodiment illustrated in FIG. 2A, the thermally conductive sheet 118 may be in direct contact with the surface of the heat sink 102, a thermal limiting component 112a, and/or a non-thermal limiting component 112b. In this non-limiting embodiment, the thermally conductive sheet 118 may include an adhesive liner to maintain physical contact with the surface of the heat sink 102, thermal limiting components 112a, and/or non-thermal limiting component 112b. In other embodiments, the thermally conductive sheet 118 may not be in physical contact with one or more of these components. For example, as illustrated in FIG. 2B, the thermally conductive sheet 118 is not in physical contact with the heat sink 102. In the non-limiting embodiment depicted in FIG. 2B, a space separates the thermally conductive sheet 118 from the heat sink 102. A thermally conductive gap filler 120 may be disposed in this space to facilitate thermal contact between the thermally conductive sheet 118 and the heat sink 102, as described in more detail below.

Referring again to FIG. 1, the thermally conductive sheet 118 may also span a high-voltage isolation boundary of the power supply 104. High-voltage isolation boundaries are physical or electric barriers that separate high-voltage circuits from low-voltage circuits to protect users and electrical components from high voltage and electrical surges. For example, insulation around the high-voltage components can provide a physical high-voltage isolation boundary. Examples of electrical isolation barriers can include transformers and optocouplers. High-voltage isolation boundaries are essential for compliance with safety standards, particularly for industrial electronic systems which often employ higher voltages. Referring to the present disclosure, the thermally conductive sheet 118 may span a high-voltage isolation boundary and contact high-voltage circuits on one end and low-voltage circuits on the other. To prevent electrical shorting across this high-voltage isolation boundary, the thermally conductive sheet 118 may be insulated with a non-conductive material, as described in more detail in FIG. 4 that follows.

The apparatus 100 may also include thermal interface material 122 disposed on the substrate 110. Thermal interface material 122 can protect the heat-generating components 112 from environmental factors such as dust and moisture. Thermal interface material 122 may also be electrically isolating and thermally conductive. Accordingly, the thermal interface material 122 may reduce electrical shorting and enhance the distribution of heat through the power supply 104. Thermal interface material 122 may be any material suitable for isolating electricity and spreading heat. For example, the thermal interface material 122 may be composed of silicone rubber. Other examples of thermal interface material 122 include but are not limited to epoxy resin, thermoplastic polymers, and acrylic resins.

Referring again to FIG. 2A, the thermal interface material 122 may be disposed on the substrate 110 in thermal contact with at least one non-thermal limiting component 112b and the thermally conductive sheet 118. In the non-limiting example illustrated in FIG. 1, the thermal interface material 122 may be disposed on the substrate 110 to extend between the thermal limiting components 112a and the non-thermal limiting components 112b in some areas, and to cover some non-thermal limiting components 112b in other areas. The thermal interface material 122 thereby thermally joins the thermal limiting components 112a to the non-thermal limiting component 112b. Heat generated by the thermal limiting components 112a is thereby spread in the x-y direction to the non-thermal limiting components 112b via the thermal interface material 122, which reduces the temperature of the thermal limiting components 112a. Heat generated by the thermal limiting components 112a is also spread first along the x-y direction via the thermally conductive sheet 118 and then in the negative z-direction from the thermally conductive sheet 118 to the non-thermal limiting components 112b via the thermal interface material 122, which further reduces the temperature of the thermal limiting components 112a.

The apparatus 100 may also include gap filler 120 disposed in thermal contact with the thermally conductive sheet 118 and at least one non-thermal limiting component 112b. Gap filler 120 may protect the electrical components from mechanical vibration. Gap filler 120 may also enhance heat distribution away from the thermal limiting components 112a and prevent electrical shorts. Gap filler 120 may be any appropriate material that can conduct heat in an electronic device. For example, the gap filler 120 may be polyurethane. Other examples of gap filler 120 include but are not limited to silicone and epoxy resin. Referring to FIG. 2A, gap filler 120 may be disposed between the thermal interface material 122 and the thermally conductive sheet 118. Gap filler 120 thermally joins the thermally conductive sheet 118 to the non-thermal limiting components 112b. Heat generated by the thermal limiting components 112a is thereby spread in the negative z-direction to the non-thermal limiting components 112b, which reduces the temperature of the thermal limiting components 112a. In this exemplary embodiment, the thermally conductive sheet 118 is in physical contact with the gap filler 120 on one side and the heat sink 102 on the other side. Referring to FIG. 2B, in an alternative embodiment, the thermally conductive sheet 118 is not in physical contact with the heat sink 102 as the result of a space. In this embodiment, gap filler 120 may also be disposed between the thermally conductive sheet 118 and the heat sink 102 to provide thermal contact between the thermally conductive sheet 118 and the heat sink 102. Heat generated by the thermal limiting components 112a can thereby spread in the positive z-direction to the heat sink 102 to reduce the temperature of the thermal limiting components 112a.

Referring again to FIG. 1, the apparatus 100 may also include near-capacity components 112c. Near-capacity components 112c are a subset of heat-generating components 112. As previously mentioned, the functionality of heat-generating components 112 is at least partially dependent on their temperature, and heat-generating components 112 have varying temperature and power ratings. Near-capacity components 112c are heat-generating components 112 that are characterized by a tendency to operate at or around their maximum temperature rating such that the transfer of additional heat from other heat-generating components 112 would cause the near-capacity components 112c to exceed their maximum temperature rating, thereby transforming the near-capacity components 112c into thermal limiting components. Accordingly, it may be desirable to avoid transferring heat to near-capacity components 112c. As such, it may be desirable to avoid thermal contact between thermally conductive components of the power supply 104 and the near-capacity components 112c. For example, the thermally conductive sheet 118 may be sized and positioned to avoid thermal contact with the surface of the near-capacity components 112c. Without thermal contact between the thermally conductive sheet 118 and the near-capacity components 112c, heat generated by the thermal limiting components 112a is not spread to the near capacity components 112c through the thermally conductive sheet 118. Similarly, the thermal interface material 122 may be strategically disposed only on a portion of the substrate 110, avoiding the area of the substrate 110 that surrounds the near-capacity components 112c. In addition or in the alternative, the thermally conductive sheet 118 could have one or more apertures in geometric shapes, like squares or circles, formed into the conductive sheet 118 to prevent or at least limit heat transfer to certain heat generating components 112, like near-capacity components 112c. For example, the thermally conductive sheet 118 may include a square-shaped aperture formed above one or more near-capacity components 112c to limit heat transfer to the near-capacity component 112c. Without thermal contact between the thermal interface material 122 and the near-capacity components 112c, heat generated by the thermal limiting components 112a is not spread to the near-capacity components 112c through the thermal interface material 122. Accordingly, heat may be strategically distributed throughout the power supply 104 without compromising the performance of the near-capacity components 112c.

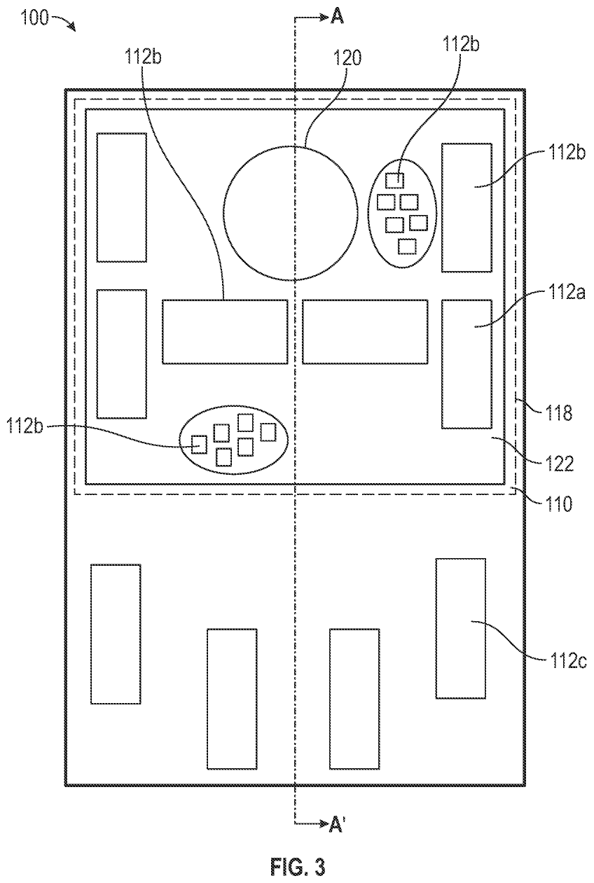

Referring to FIG. 3, illustrated is a top view of an exemplary apparatus 100 in accordance with the disclosed principles. In this non-limiting exemplary embodiment, thermal limiting components 112a, non-thermal limiting components 112b, and near-capacity components 112c may be mounted on the substrate 110. As previously discussed, thermal interface material 122 may be disposed on the substrate 110. In this non-limiting exemplary embodiment, thermal interface material 122 is strategically disposed on the substrate 110 to be in thermal contact with thermal limiting components 112a and non-thermal limiting components 112b, while avoiding thermal contact with near-capacity components 112c. Heat generated by the thermal limiting components 112a is thereby selectively spread to the non-thermal limiting components 112b, and not to the near-capacity components 112c. Similarly, the thermally conductive sheet 118 may be sized and positioned to be in thermal contact with the surface of at least one thermal limiting component 112a and optionally at least one non-thermal limiting component, while avoiding thermal contact with the near-capacity components 112c. Heat generated by the thermal limiting components 112a is thereby selectively spread through the thermally conductive sheet 118 to the heat sink 102 (not shown) and non-thermal limiting components 112b, and not to the near-capacity components 112c. As previously discussed, gap filler 120 may be disposed in thermal contact with the thermally conductive sheet 118 and at least one non-thermal limiting component 112b. In this non-limiting embodiment, gap filler 120 is disposed between the thermal interface material 122 and the thermally conductive sheet 118.

Referring to FIG. 4, illustrated is an exploded view of an exemplary embodiment of a thermally conductive sheet 400 for use with the apparatus 100. In this non-limiting exemplary embodiment, the thermally conductive sheet 400 includes a graphite sheet 402 and at least one electrically insulative sheet 404a, 404b. As previously discussed, graphite has a relatively high heat conductivity. However, graphite is also an electrical conductor, which can cause electrical shorting. It may therefore be advantageous to insulate the graphite sheet 402 with a non-conductive material to limit electrical conduction. The electrically insulative sheet 404a, 404b may be formed from any appropriate non-conducting material. For example, the electrically insulative sheet 404a, 404b may be composed of polyimide film or a polyethylene terephthalate film. Other examples of materials that can be used to form an electrically insulative sheet 404a, 404b include but are not limited to polytetrafluoroethylene, polyurethane, and polyamide. The electrically insulative sheet 404a, 404b is sized to be at least as large as the graphite sheet 402. In the non-limiting exemplary embodiment, the graphite sheet 402 is disposed between two electrically insulative sheets 404a, 404b. The edges of the electrically insulative sheets 404a, 404b may be joined together to enclose the graphite sheet 402. For example, the edges of the electrically insulative sheets 404a, 404b may include an adhesive lining. The adhesive lining may also extend across the surface of the electrically insulative sheet 404a, 404b to maintain physical contact between the surface of the electrically insulative sheet 404a, 404b and the graphite sheet 402. As previously discussed, the surfaces of the thermally conductive sheet 118 may also include an adhesive liner to maintain physical contact with the surface of the heat sink 102, thermal limiting components 112a, and/or non-thermal limiting component 112b.

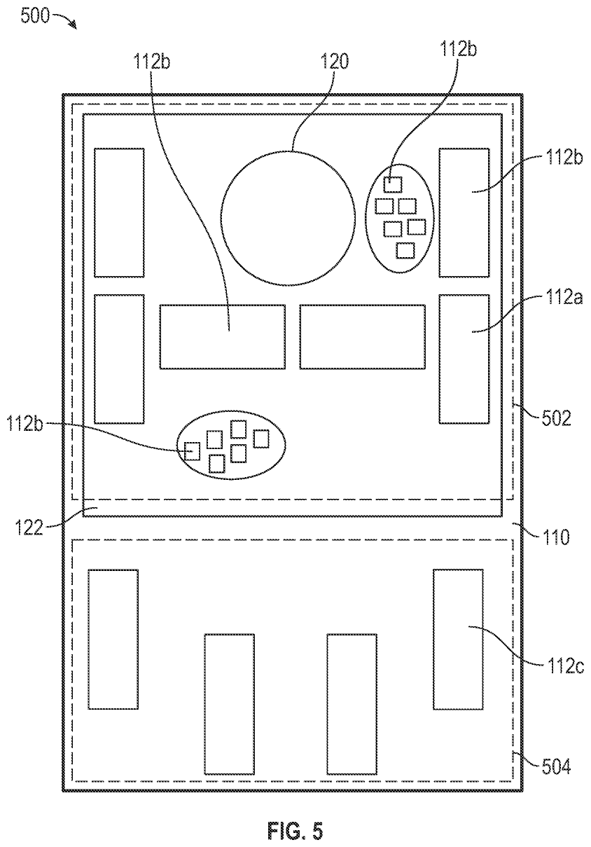

Referring to FIG. 5, illustrated is another exemplary embodiment of an apparatus 500 in accordance with the disclosed principles. In this non-limiting exemplary embodiment, the apparatus 500 may include more than one thermally conductive sheet 502, 504 that are strategically positioned to be in thermal contact with particular heat-generating components 112 based on thermal tolerance.

For example, the presence of too many thermally limiting components in proximity to a non-thermally limiting component could cause the transfer of too much heat to the non-thermally limiting component if a thermally conductive sheet permitted heat transfer from the thermally limiting components to the non-thermally limiting component. As a result, the non-thermally limiting component could exceed its maximum temperature rating and become a thermally limiting component. Alternatively, a thermally conductive sheet in thermal contact with a large number of thermally limiting components, particularly in close proximity to each other, may be unable to adequately distribute enough of the heat to non-thermally limiting components 112b. Thus, two or more thermally conductive sheets can be used to further control the distribution of heat.

In the non-limiting exemplary embodiment depicted in FIG. 5, a first thermally conductive sheet 502 provides a means to draw heat away from the thermal limiting components 112a and a second thermally conductive sheet 504 that provides a means to draw heat away from one or more other heat generating components, like thermal limiting components and/or near thermal capacity components. In this illustrative embodiment, the second thermally conductive sheet 502 draws heat away from near capacity component 112c.

The first thermally conductive sheet 502 may be positioned to be in thermal contact with at least one thermally limiting component 112a and optionally at least one non-thermal limiting component 112b, and to avoid thermal contact with the near capacity components 112c. Heat generated by the thermal limiting components 112a is thereby spread through the first thermally conductive sheet 502 to the heat sink 102 (not shown) and to the non-thermal limiting components 112b, and is not spread to the near-capacity components 112c. As previously discussed, this arrangement allows for cooling of the thermal limiting components 112a without spreading heat to the near capacity components 112c, which have a lower heat tolerance.

The second thermally conductive sheet 504 may be sized and positioned to be in thermal contact with the surface of at least one near capacity component 112c, and to avoid thermal contact with the thermal limiting components 112a and non-thermal limiting components 112b. Heat generated by the near capacity component 112c may thereby be spread into the second thermally conductive sheet 504 and the temperature of the near capacity component 112c is decreased. The surface area of the second thermally conductive sheet 504 may be larger than the area of contact with the near capacity component 112c such that the second thermally conductive sheet 504 spreads heat from the near capacity component 112c in the x-y direction, thereby further reducing the temperature of the near capacity component 112c. Like the first thermally conductive sheet 502, the second thermally conductive sheet 504 may also be sized and positioned to be in thermal contact with the heat sink 102 (not shown). Accordingly, the near capacity component 112c are thermally joined to the heat sink 102 by the second thermally conductive sheet 504. Heat generated by the near capacity component 112c is thereby spread in the positive z-direction to the heat sink 102. In this way, the second thermally conductive sheet 504 acts as a heat spreader to dissipate the heat generated by the near capacity component 112c into the surrounding environment.

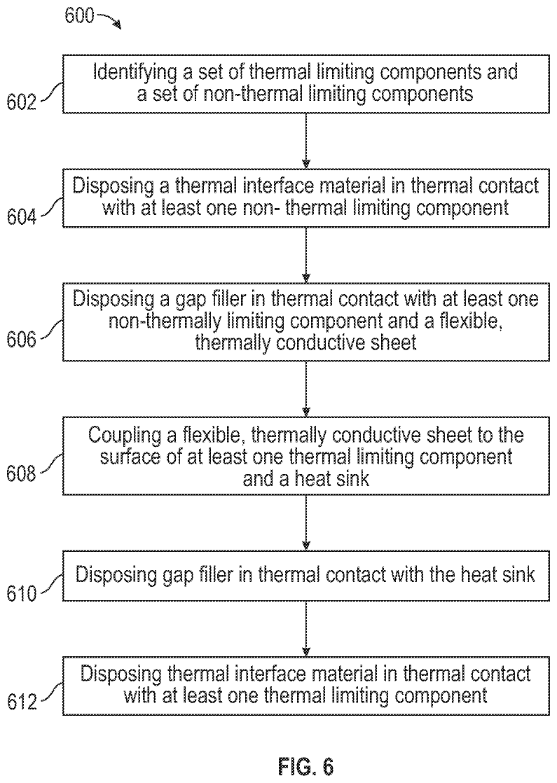

Referring to FIG. 6, illustrated is a flowchart of the method of dissipating heat generated by heat-generating components of an electronic device in accordance with the disclosed principles. Flowchart 600 begins at step 602 by identifying the thermal limiting components 112a and the non-thermal limiting components 112b from the plurality of heat-generating components 112 mounted on the substrate 110 of the power supply 104. As previously discussed, thermal limiting components 112a are heat-generating components 112 that tend to exceed their maximum temperature rating and cause reduced performance to avoid damage from overheating, while non-thermal limiting components 112b tend to operate below their maximum temperature rating.

In step 604, thermal interface material 122 is disposed in thermal contact with at least one non-thermal limiting component 112b. Step 604 may optionally also include disposing thermal interface material 122 in thermal contact with at least one thermal limiting component 112a. In a non-limiting embodiment, the thermal interface material 122 may be disposed on the substrate 110 to extend between the thermal limiting components 112a and the non-thermal limiting components 112b in some areas, and to cover some non-thermal limiting components 112b in other areas.

In step 606, gap filler 120 is disposed in thermal contact with at least one non-thermally limiting component 112b and the thermally conductive sheet 118. In a non-limiting embodiment, gap filler 120 may be disposed between the thermal interface material 122 and the thermally conductive sheet 118.

In step 608, the thermally conductive sheet 118 is coupled to the surface of at least one thermal limiting component 112a on one side and the heat sink 102 on the opposite side. Coupling the thermally conductive sheet 118 to a thermal limiting component 112a forms a heat-conductive pathway in the x-y plane that is generally parallel to the substrate. Coupling the thermally conductive sheet 118 to the heat sink forms a heat conductive pathway in the z-direction that is generally perpendicular to the substrate 110. Step 608 may optionally include coupling the thermally conductive sheet 118 to the surface of at least one non-thermal limiting component 112b.

In step 610, the heat generated by the coupled thermal limiting component 112a is spread along the heat-conductive pathway in the x-y plane generally parallel to the substrate 110. In a non-limiting embodiment, the surface area of the thermally conductive sheet 118 may be larger than the area of contact with the thermally limiting component 112a such that heat generated by the thermal limiting component 112a is spread across the x-y plane.

In step 612, the heat generated by the coupled thermal limiting component 112a is spread along the heat-conductive pathway in the negative-z direction to the coupled non-thermal limiting component 112b and in the positive z-direction to the heat sink 102. In a non-limiting embodiment, heat is spread in the negative z-direction to the non-thermal limiting components 112b through the gap filler 120 and thermal interface material 122. In a non-limiting embodiment, heat is spread in the positive z-direction to the heat sink 102. In an alternative non-limiting exemplary embodiment, heat is spread in the positive z-direction to the heat sink 102 through the gap filler 120.

Heat generated by the thermal limiting components 112a is thereby distributed away from the thermal limiting components 112a, and toward the heat sink 102 and the non-thermal limiting components 112b, to prevent the thermal limiting components 112a from exceeding their maximum temperature rating and limiting performance of the power supply 104.

While this disclosure has been particularly shown and described with reference to preferred embodiments, it will be understood by those skilled in the pertinent field of art that various changes in form and detail may be made therein without departing from the spirit and scope of the invention. The inventors expect skilled artisans to employ such variations as appropriate, and the inventors intend the invention to be practiced otherwise than as specifically described herein. Accordingly, this disclosure includes all modifications and equivalents of the subject matter recited in the claims appended hereto, as permitted by applicable law. Moreover, any combination of the above-described elements in all possible variations thereof is encompassed by the disclosure unless otherwise indicated herein or otherwise clearly contradicted by context.

Also, while various embodiments in accordance with the principles disclosed herein have been described above, it should be understood that they have been presented by way of example only, and not limitation. Thus, the breadth and scope of this disclosure should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, and by way of example, although the headings refer to a “Technical Field,” the claims should not be limited by the language chosen under this heading to describe the so-called field. Further, a description of a technology as background information is not to be construed as an admission that certain technology is prior art to any embodiment(s) in this disclosure. Neither is the “Summary” to be considered as a characterization of the embodiment(s) set forth in issued claims. Furthermore, any reference in this disclosure to “invention” in the singular should not be used to argue that there is only a single point of novelty in this disclosure. Multiple embodiments may be set forth according to the limitations of the multiple claims issuing from this disclosure, and such claims accordingly define the embodiment(s), and their equivalents, that are protected thereby. In all instances, the scope of such claims shall be considered on their own merits in light of this disclosure, but should not be constrained by the headings set forth herein.

Moreover, the Abstract is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the claims reflect, inventive subject matter lies in less than all features of a single disclosed embodiment. Thus, the following claims are hereby incorporated into the Detailed Description, with each claim standing on its own as a separate embodiment.

Any and all publications, patents, and patent applications cited in this disclosure are herein incorporated by reference as if each were specifically and individually indicated to be incorporated by reference and set forth in its entirety herein.

We claim:

1. An apparatus comprising:
a power supply; and
a heat sink at least partially enclosing the power supply, wherein the power supply further comprises:
a substrate defining a generally planar body having a first side and a second side;
a plurality of electrical components generating heat during operation of the power supply and disposed about the first side of the substrate, wherein the plurality of electrical components includes a set of thermal limiting components and a set of non-thermal limiting components; and
a flexible, thermally conductive sheet coupled to a surface of one or more of the set of thermal limiting components and the heat sink, wherein the flexible, thermally conductive sheet transfers heat from at least one component from the set of thermal limiting components on a first side of the flexible, thermally conductive sheet to the heat sink on an opposite side of the flexible, thermally conductive sheet.

2. The apparatus of claim 1, wherein the flexible, thermally conductive sheet is further thermally coupled with at least one component from the set of non-thermal limiting components.

3. The apparatus of claim 2, further comprising a thermally conductive gap filler disposed in thermal contact with the flexible, thermally conductive sheet and the at least one component from the set of non-thermal limiting components.

4. The apparatus of claim 3, further comprising a thermal interface material disposed between the at least one component from the set of non-thermal limiting components and the thermally conductive gap filler.

5. The apparatus of claim 1, further comprising a thermally conductive gap filler.

6. The apparatus of claim 1, wherein the heat sink is a casing that at least partially encloses the power supply.

7. The apparatus of claim 6, further comprising a thermally conductive gap filler applied between the flexible, thermally conductive sheet and the casing.

8. The apparatus of claim 1, wherein the flexible, thermally conductive sheet spans a high-voltage isolation boundary of the power supply.

9. The apparatus of claim 1, wherein the flexible, thermally conductive sheet is formed from a graphite sheet and at least one electrically insulative sheet that has a size that is at least as large as the graphite sheet.

10. The apparatus of claim 9, wherein the at least one insulative sheet is formed from polyimide film or polyethylene terephthalate film.

11. The apparatus of claim 9, wherein the graphite sheet is enclosed in an enveloped formed from the at least one electrically insulative sheet and another electrically insulative sheet.

12. The apparatus of claim 1, wherein the flexible, thermally conductive sheet is sized and positioned to avoid contact with near-capacity components from the set of thermal limiting components.

13. The apparatus of claim 1, further comprising a conductive heat pathway leading from the set of thermal limiting components to the set of non-thermal limiting components and the heat sink, wherein the conductive heat pathway initially spreads heat in an X-Y plane generally parallel to the substrate, then spreads the heat in a negative Z-direction to the set of non-thermal limiting components and in a positive Z-direction to the heat sink.

14. A system comprising:
a power module that includes a heat sink configured to at least partially enclose a power supply; and
a set of subsystems electrically coupled to the power module, wherein the power supply comprises:
a set of thermal limiting components disposed on a substrate, wherein the thermal limiting components are electrical components that tend to exceed their maximum operating temperature during operation of the power supply;
a set of non-thermal limiting components disposed on a substrate, wherein the non-thermal limiting components are electrical components that tend to operate below their maximum operating temperature;
a flexible, thermally conductive sheet coupled to a surface of at least one component from the set of thermal limiting components and the heat sink, wherein:
the thermal limiting components and thermal non-limiting components generate heat during operation of the power supply,
the flexible, thermally conductive sheet distributes heat from the thermal limiting components to the heat sink, and
the heat sink distributes heat to the surrounding environment.

15. The system of claim 14, wherein the flexible, thermally conductive sheet is further thermally coupled with at least one component from the set of non-thermal limiting components, and wherein the flexible, thermally conductive sheet distributes heat from the thermal limiting components to the non-thermal limiting components.

16. The system of claim 15, further comprising a thermally conductive gap filler disposed in thermal contact with the flexible, thermally conductive sheet and the at least one component from the set of non-thermal limiting components.

17. The system of claim 16, further comprising a thermal interface material disposed between the at least one component from the set of non-thermal limiting components and the thermally conductive gap filler.

18. A method for manufacture of an apparatus for achieving a more uniform distribution of heat across the various components within an electronic device, comprising:
identifying a set of thermal limiting components and a set of non-thermal limiting components from a plurality of electrical components of a power supply, wherein the electrical components are disposed on a substrate defining a generally planar body having a first side and a second side;
disposing a thermal interface material in thermal contact with at least one component from the set of non-thermal limiting components;
disposing a gap filler in thermal contact with a flexible, thermally conductive sheet and at least one component from the set of non-thermally limiting components; and
coupling the flexible, thermally conductive sheet to a surface of at least one component from the set of thermal limiting components on a first side of the flexible, thermally conductive sheet and a heat sink on an opposite side of the flexible, thermally conductive sheet.

19. The method of claim 18, wherein disposing the gap filler in thermal contact with the flexible, thermally conductive sheet further comprises:
disposing the gap filler in thermal contact with the heat sink.

20. The method of claim 19, wherein disposing the thermal interface material in thermal contact with at least one component from the set of non-thermal limiting components further comprises:
disposing the thermal interface material in thermal contact with at least one component from the set of thermal limiting components.
